(19) United States
(12) Patent Application Publication
(10) Pub. No.: US 2010/0163991 A1
(43) Pub. Date: Jul. 1, 2010

(54) LATERALLY DOUBLE-DIFFUSED METAL OXIDE SEMICONDUCTOR, AND METHOD FOR FABRICATING THE SAME

(76) Inventors: Hyun-Dong Kim, Yuseong-gu (KR); Seung-Man Jung, Hwaseong-si (KR)

Correspondence Address: SHERR & VAUGHN, PLLC, 620 HERNDON PARKWAY, SUITE 320, HERNDON, VA, 20170, US

(21) Appl. No.: 12/646,634

(22) Filed: Dec. 23, 2009

(30) Foreign Application Priority Data
Dec. 31, 2008 (KR) 10-2008-0138070

(51) Int. Cl. H01L 29/78; H01L 21/336

(52) U.S. Cl. 257/343; 438/286; 257/E29.261; 257/E21.417

(57) ABSTRACT

A laterally double-diffused metal oxide semiconductor (LDMOS) and a method for fabrication thereof includes a well region formed in a semiconductor substrate having an active region defined by device isolation layers, a body region formed over the well region, a drain region spaced from the body region at a constant interval and formed above the well region, a source region and a source contact region formed in the body region in structural communication with the source region, a drift region having a trench formed therein formed in the well region between the body region and the drain region, and a gate formed over the semiconductor substrate which partially overlaps the source region and the drift region.

The present application claims priority under 35 U.S.C. §119 to Korean Patent Application No. 10-2008-0138070 (filed on Dec. 31, 2008), which is hereby incorporated by reference in its entirety.

### BACKGROUND

Initial double diffused metal oxide semiconductors (DMOS) for high power devices and/or smart ICs have a vertical structure including a control gate and two sources placed on and/or over a silicon substrate and a drain formed at a bottom thereof so as to be switched on/off in accordance with applied voltage of the gate, thereby being used as a switching device.

Such a vertical type DMOS, however, exhibits high current leakage and cannot have a System-on-Chip (SOC) structure due to structural limitations thereof. In order to overcome such shortcomings and to embody a SOC structure, an LDMOS has been proposed. In particular, a high voltage LDMOS has a field oxide film as a device isolation layer between a gate and a drain, and the gate is extended from a source and overlapped with a partial region of the field oxide film. For techniques regarding less than 0.25 um grade LDMOS, instead of a local oxidation of silicon (LOCOS) structure, a shallow trench isolation (STI) structure is used as a device isolation layer to increase a density of a logic device. Since the LDMOS has a horizontal arrangement that includes a gate, a source region and a drain region, it has low integration. Moreover, a problem of increased undesired parasitic resistance is caused.

### SUMMARY

Embodiments are related to a semiconductor device such as a laterally double-diffused metal oxide semiconductor (LDMOS) and a method for fabrication thereof.

Embodiments are related to an LDMOS and a method for fabrication thereof with enhanced device integration and decreased parasitic resistance.

Embodiments are related to an LDMOS and a method for fabrication thereof that enables easy migration of electrons from a source region into a drain region.

In accordance with embodiments, an LDMOS can include at least one of the following: an N well region formed in a semiconductor substrate which has an active region defined by a device isolation layer; a body region formed on and/or over the N well region; a drain region spaced from the body region by a constant interval and formed on and/or over the N well region; a source region formed in the body region and a source contact region structurally communicating with the source region; a drift region formed between the body region and the drain region on and/or over the N well region, the drift region having a trench formed at an upper surface thereof; a P-doped push-pull region formed under the drift region; and a gate having a first section partially overlapped with the source region while a second section overlapped with the drift region.

In accordance with embodiments, a method for fabrication of an LDMOS can include at least one of the following: forming an N type well in a semiconductor substrate; forming a body region by ion-implanting impurities on and/or over a first portion of the upper surface of the N type well; forming a drift region having a trench structure by ion-implanting impurities on and/or over a second portion of the upper surface of the N type well to form; forming a device isolation layer having an STI structure to define an active region in the semiconductor substrate; forming a source contact region by ion-implanting high concentration impurities into the body region; forming a source region structurally communicating with the source contact region; forming a drain region by ion-implanting impurities into the N type well between the drift region and the device isolation layer; and then forming a gate on and/or over the semiconductor substrate such that a first section of the gate overlaps the source region and a second section of the gate overlaps the drift region. In accordance with embodiments, another trench can be formed in the drift region during formation of the trench for the device isolation layer and a push-pull region can be formed under the drift region using P-doping.

In accordance with embodiments, an LDMOS can include at least one of the following: an N well region formed in a semiconductor substrate having an active region defined by device isolation layers; a body region formed over the N well region; a drain region spaced from the body region at a constant interval and formed above the N well region; a source region formed in the body region; a source contact region formed in the body region in structural communication with the source region; a drift region formed in the N well region between the body region and the drain region, the drift region including a trench formed therein; and a gate formed over the semiconductor substrate which partially overlaps the source region and the drift region.

In accordance with embodiments, a method for fabrication of an LDMOS can include at least one of the following: forming an well in a semiconductor substrate; forming a body region in the well by ion-implanting impurities in the well; forming a drift region having a trench structure in the well by ion-implanting impurities; forming device isolation layers to define an active region in the semiconductor substrate; forming a source region in the body region by ion-implanting high concentration impurities into the body region; forming a source contact region in the body region and in structural communication with the source region by ion-implanting high concentration impurities into the body region; forming a drain region in the well between the drift region and one of the device isolation layers by ion-implanting impurities into the well; and then forming a gate over the semiconductor substrate such that a portion of the gate overlaps the source region and another portion of the gate overlaps the drift region.

In accordance with embodiments, a method for fabrication of an LDMOS can include at least one of the following: forming a well in a semiconductor substrate; forming a body region in the well; forming a drift region in the well; simultaneously forming a plurality of first trenches in a device isolation region of the semiconductor substrate and a second trench in the drift region; forming device isolation layers by filling the first trenches with a field oxide film; forming a source region in the body region; forming a source contact region in the body region and in structural communication with the source region; forming a drain region in the well between the drift region and one of the device isolation layers; forming push-pull region in the well region below the drift region; and then forming a gate over the semiconductor substrate such that a first portion of the gate overlaps the source region and a second portion of the gate overlaps the drift region.

### DRAWINGS

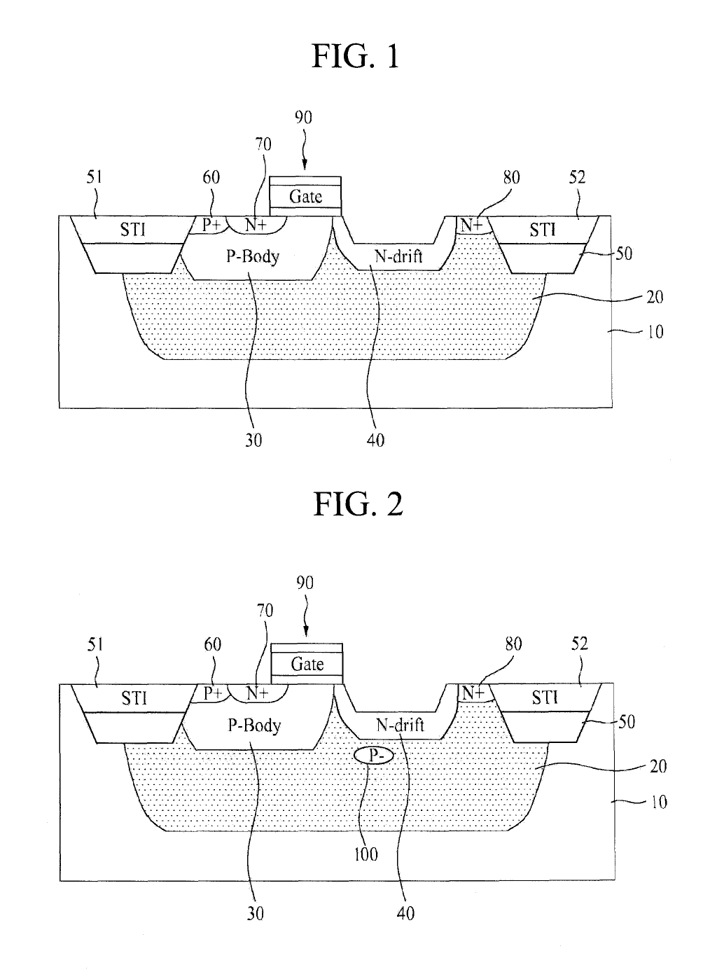

Example FIGS. 1 illustrate an N type LDMOS structure, in accordance with embodiments.

### DESCRIPTION

Other purposes, characteristics and/or advantages of embodiments will be described in detail.

Hereinafter, technical configurations and functional effects of will be clearly described in conjunction with accompanying drawings. Such technical configurations and functional effects of embodiments are concretely explained with reference to the accompanying drawings, which should not be construed to restrict technical ideas, essential configurations and effects of such embodiments.

Example FIG. 1 illustrates a structure of an N type LDMOS in accordance with embodiments.

As illustrated in example FIG. 1, an N type LDMOS can include semiconductor substrate 10, N well region 20, P type body region 30, N-drift region 40, first device isolation layer 51 and second device isolation layer 52 each having an STI structure, source contact region 60, source region 70, drain region 80 and gate 90.

Semiconductor substrate 10 may be a P type substrate in which N well region 20 is formed. Semiconductor substrate 10 includes first device isolation layer 51 and second device isolation layer 52 each having an STI structure. First device isolation layer 51 and second device isolation layer 52 may be composed of an insulating material such as a field oxide film to thereby define an active region of the substrate. Silicon oxide film (SiO) 50 may be formed under first device isolation layer 51 and second device isolation layer 52 in order to enhance device isolation reliability.

P type body region 30, N-drift region 40 having a trench formed therein, source contact region 60, source region 70 and drain region 80 are each formed in the active region. P type body region 30 is formed in N well region 20 such that an upper portion thereof is spatially above N well region 20. N well region 20 includes drain region 80 containing N+impurities injected therein. Drain region 80 is spaced from P type region 30 by a constant interval. Source region 70 containing N+ impurities injected in P type body region 30. Source contact region 60 is formed by injecting high concentration P+ impurities into P type body region 30. Source contact region 60 is formed directly adjacent to and in structural communication with source region 70.

N-drift region 40 is placed between drain region 80 and gate 90 in N well region 20. N-drift region 40 has a trench structure formed at an upper surface thereof In particular, the trench of N-drift region 60 is simultaneously formed simultaneously with trenches used to form first device isolation layer 51 and second device isolation layer 52.

Gate 90 is formed in the active region on and/or over semiconductor substrate 10 including P type body region 30, N-drift region 40, source contact region 60, source region 70 and drain region 80. Gate 90 is formed in a gate formation region and includes a first portion that partially overlaps source region 70 and a second portion that partially overlaps N-drift region 40. Accordingly, gate 90 extends from a partial area of source region 70 to an upper area of N-drift region 40.

N channel type LDMOS includes N-drift region 40 having a trench between gate 90 and drain region 80, which in turn isolates a channel region from drain region 80 below gate 90. Especially, a trench is present in N-drift region 40, effectively extending the drift region.

Example FIG. 2 is a cross-sectional view illustrating an N channel type LDMOS structure in accordance with embodiments. The N channel type LDMOS illustrated in example FIG. 2 has almost the same structure as embodiments illustrated in example FIG. 1, with the exception that P-doped push-pull region 100 is formed in N well region 20 below the N-drift region 40.

As illustrated in example FIG. 2, P-doped push-pull region 100 conducts push-pull of electrons flowing from source region 70 into drift region 40 having a trench and toward drain region 80, thereby allowing easy migration of electrons into drain region 80.

Hereinafter, a process for fabricating an N channel type LDMOS illustrated in example FIGS. 1 and 2 will be described in detail. N channel type LDMOS includes an N type well 20 formed in semiconductor substrate 10. P type body region 30 is formed by ion-implanting impurities through a first photoresist pattern to partially expose a surface of substrate 10 corresponding to the active region. In this regard, semiconductor substrate 10 may be a P type substrate and, after formation of P type body region 30, annealing may be conducted.

A second photoresist pattern is formed to expose another portion of the surface of semiconductor substrate 10 corresponding to the active region. Impurities are then ion-implanted to form N-drift region 40 before formation of a trench. First device isolation layer 51 and second device isolation layer 52 having STI structures are formed and composed of a field oxide film to thereby define an active region in semiconductor substrate 10. In order to form first device isolation layer 51 and second device isolation layer 52, a plurality of trenches are initially formed, including a trench formed in N-drift region 40. Silicon oxide film 50 may be further formed under first device isolation layer 51 and second device isolation layer 52. Specifically, a third photoresist pattern is formed to expose a device isolation regions and also an upper surface of N-drift region 40. An etching process such as an anisotropic etching process is then performed using the third photoresist pattern as a mask to form trenches in the device isolation regions and also an upper surface of N-drift region 40. A field oxide film is embedded only into the trenches at the device isolation regions to define the active region of semiconductor substrate 10.

Furthermore, an etching window to expose an upper portion of N-drift region 40 in the third photoresist pattern has a smaller width than that of the N-drift region. N-drift region 40 having a trench structured is placed adjacent to P type body region 30 but is spaced therefrom by a constant interval. After formation of N-drift region 40 having the trench, P-doping is carried out to form push-pull region 100 under N-drift region 40.

Ion-implanting N+ impurities into P type body region 30 is then performed to thereby form in P type body region 30 itself source region 70 and source contact region 60 structurally communicating with source region 70. Source contact region 60 is formed by ion-implanting high concentration P+ impurities. The high concentration P+ impurities are ion-implanted into P type body region 30 to form source contact region 70 such that source region 70 structurally communicated with source contact region 60. The source region 70 is prepared by ion-implanting N+ impurities. Subsequently, N+ impurities are ion-implanted into N well region 20 to form drain region 80 which is placed between N-drift region 40 having the trench and any one of first device isolation layer 51 and second device isolation layer 52 to define the active region.

As described above, gate 90 is formed on and/or over semiconductor substrate 10. Gate 90 is formed in a gate formation region of substrate 10 such that a first portion of gate 90 partially overlaps source region 70 and a second portion partially overlaps N-drift region 40.

In accordance with embodiments, a drift region is formed with a trench structure, thus achieving extension of the drift region. As a result, compared to general techniques, embodiments may form a drift region with a relatively narrower width, thereby enhancing device integration. Moreover, a P-doped push-pull region is further formed below the drift region so as to conduct push-pull of electrons flowing from the source region to the drift region, toward the drain region. Consequently, electron migration to the drain region may be easily performed.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
an N well region formed in a semiconductor substrate having an active region defined by device isolation layers;
a body region formed over the N well region;
a drain region spaced from the body region at a constant interval and formed above the N well region;
a source region formed in the body region;
a source contact region formed in the body region in structural communication with the source region;
a drift region formed in the N well region between the body region and the drain region, wherein the drift region includes a trench formed therein; and
a gate formed over the semiconductor substrate which partially overlaps the source region and the drift region.

2. The apparatus of claim 1, wherein the body region is a P type body region, the drain region and the source region contain N+ impurities ion-implanted therein, respectively, the source contact region contains high concentration P+ impurities ion-implanted therein, and the drift region is an N-drift region.

3. The apparatus of claim 2, wherein the LDMOS is an N channel type LDMOS.

4. The apparatus of claim 1, further comprising a silicon oxide film below the device isolation layer.

5. The apparatus of claim 1, further comprising a P-doped push-pull region under the drift region.

6. The apparatus of claim 1, wherein the apparatus comprises a laterally double-diffused metal oxide semiconductor.

7. A method comprising:
forming an well in a semiconductor substrate;
forming a body region in the well by ion-implanting impurities in the well;
forming a drift region having a trench structure in the well by ion-implanting impurities;
forming device isolation layers to define an active region in the semiconductor substrate;
forming a source region in the body region by ion-implanting high concentration impurities into the body region;
forming a source contact region in the body region and in structural communication with the source region by ion-implanting high concentration impurities into the body region;
forming a drain region in the well between the drift region and one of the device isolation layers by ion-implanting impurities into the well; and then
forming a gate over the semiconductor substrate such that a portion of the gate overlaps the source region and another portion of the gate overlaps the drift region.

8. The method of claim 7, further comprising formation of another trench in the drift region when the trench for the device isolation layer is formed.

9. The method of claim 7, further comprising formation of a push-pull region under the drift region by P-doping.

10. The method of claim 7, wherein the well comprises an N type well.

11. The method of claim 7, wherein the body region comprises a P type body region.

12. The method of claim 7, wherein the device isolation layers have a shallow trench isolation structure.

13. A method comprising:
forming a well in a semiconductor substrate;
forming a body region in the well;
forming a drift region in the well;
simultaneously forming a plurality of first trenches in a device isolation region of the semiconductor substrate and a second trench in the drift region;
forming device isolation layers by filling the first trenches with a field oxide film;
forming a source region in the body region;
forming a source contact region in the body region and in structural communication with the source region;
forming a drain region in the well between the drift region and one of the device isolation layers;
forming push-pull region in the well region below the drift region; and then forming a gate over the semiconductor substrate such that a first portion of the gate overlaps the source region and a second portion of the gate overlaps the drift region.

14. The method of claim 13, wherein forming the well comprises ion-implanting N type impurities into the semiconductor substrate.

15. The method of claim 13, wherein the semiconductor substrate comprises a P type substrate.

16. The method of claim 13, wherein forming the body region comprises:
ion-implanting P type impurities into the well; and then
performing annealing process on the semiconductor substrate.

17. The method of claim 13, wherein forming the drift region comprises ion-implanting N-type impurities into the well.

18. The method of claim 13, wherein the width of the second trench is less than the width of the drift region.

19. The method of claim 13, wherein the drift region is spaced from the body region by a constant interval.

20. The method of claim 13, wherein forming the push-pull region comprises ion-implanting P-type impurities into the well.
